(19) United States
(12) Patent Application Publication
(10) Pub. No.: US 2016/0192480 A1
(43) Pub. Date: Jun. 30, 2016

(54) ELECTRONIC DEVICE INCLUDING TRANSPARENT AND FLEXIBLE MICA SUBSTRATE AND METHOD FOR MANUFACTURING THE SAME

(71) Applicants: Samsung Electronics Co., Ltd., Suwon-si (KR); Clemson University Research Foundation, Clemson, SC (US)

(72) Inventors: Kyounghwan CHOI, Suwon-si (KR); Sung-O KIM, Pendleton, SC (US); Do Yeob KIM, Central, SC (US)

(73) Assignees: CLEMSON UNIVERSITY RESEARCH FOUNDATION, Clemson, SC (US); SAMSUNG ELECTRONICS CO., LTD., Suwon-si (KR)

(21) Appl. No.: 14/802,225

(22) Filed: Jul. 17, 2015

Related U.S. Application Data
(60) Provisional application No. 62/097,757, filed on Dec. 30, 2014.

(30) Foreign Application Priority Data
Jan. 5, 2015 (KR) 10-2015-0000474

(51) Int. Cl. H05K 1/03; H05K 3/00

(52) U.S. Cl. CPC H05K 1/0306; H05K 1/03; H05K 3/0011

(57) ABSTRACT

An electronic device including a transparent and flexible mica substrate and a method of manufacturing the electronic device are provided, in which the method includes forming an organic or inorganic layer on the mica substrate and thermally processing the mica substrate at a temperature of 200° C. or greater.

### CROSS-REFERENCE TO RELATED APPLICATION(S)

This application claims the benefit under 35 USC 119(e) of U.S. Provisional Application No. 62/097,757, filed on Dec. 30, 2014, and the benefit under 35 USC 119(a) of Korean Patent Application No. 10-2015-0000474, filed on Jan. 5, 2015, in the Korean Intellectual Property Office, the entire disclosures of which are incorporated herein by reference for all purposes.

### BACKGROUND

1. Field

The following description relates to an electronic device including a transparent and flexible mica substrate and a method of manufacturing the electronic device.

2. Description of Related Art

A transparent electronic device is fabricated based on a transparent oxide semiconductor film dissimilar to a general electronic device fabricated using an opaque semiconductor compound such as silicon, and collectively refers to optically transparent electronic devices. Using such a transparent electronic device to implement a function of information recognition, information processing, and information display may enable a reduction in spatial and visual limitations of an electronic device. The transparent electronic device may be applicable to various transparent electronic components requiring transparency including components for information recognition such as a transparent sensor and a transparent electronic security device, components for information processing such as a transparent digital and analog integrated circuit (IC), and components for information display such as a smart window and a transparent information displayer, and dye-sensitized solar cells, and the like.

Further, recent interest in a flexible device applicable to portable devices in various forms is increasing. Thus, developing mechanically flexible and optically transparent electronic devices is considered next-generation electronic technology. Such a flexible and transparent device may include a thin-film transistor, a light-emitting diode (LED), a solar cell, and a supercapacitor.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, there is provided a method of manufacturing an electronic device, the method including forming an organic or inorganic layer on a mica substrate, and thermally processing the mica substrate at a temperature of 200° C. or greater.

The mica substrate may have a thickness less than or equal to 500 micrometers (μm).

The forming of the organic or inorganic layer may include depositing a seed layer on the mica substrate and growing, from the seed layer, the organic or inorganic layer in a nanostructure.

The thermal processing may be performed subsequent to the depositing of the seed layer on the mica substrate.

The thermal processing may be performed subsequent to the growing of the organic or inorganic layer in the nanostructure.

The growing of the organic or inorganic layer in the nanostructure may use a process selected from the group consisting of plating, chemical solution deposition, physical vapor deposition, and chemical vapor deposition.

The forming of the organic or inorganic layer on the mica substrate may use a process including plating, chemical solution deposition, physical vapor deposition, or chemical vapor deposition. The organic or inorganic layer may include a transparent conductive film.

The thermally processing the mica substrate at the temperature of 200° C. or greater may include thermally processing the mica substrate at a temperature ranging from 200° C. to 750° C.

The thermally processing may result in increasing at least one of a transparency and a conductivity of the electronic device in a form including an organic or inorganic layer disposed on a mica substrate.

The thermally processing the electronic device may be performed at a temperature ranging from 200° C. to 750° C.

The organic or inorganic layer may include indium tin oxide.

In another general aspect, there is provided an electronic device including a mica substrate, and an organic or inorganic layer formed on the mica substrate. The organic or inorganic layer may include a nanostructure or a transparent conductive film, and the electronic device may be thermally processible at a temperature of 200° C. or greater.

The mica substrate may have a thickness less than or equal to 500 μm, and may be transparent and flexible.

The electronic device may be processible at a temperature ranging from 200° C. to 750° C.

The thermally processing may result in increasing at least one of a transparency and a conductivity of the electronic device.

The thermally processing the electronic device may be performed at a temperature ranging from 200° C. to 750° C.

The organic or inorganic layer may include indium tin oxide.

In another general aspect, there is provided an electronic device including a mica substrate, and an organic or inorganic layer disposed on the mica substrate. The electronic device may be manufactured by forming the organic or inorganic layer on the mica substrate, and thermally processing the mica substrate at a temperature of 200° C. or greater.

The forming of the inorganic or organic layer on the mica substrate may include depositing a seed layer on the mica substrate, and growing, from the seed layer, the organic or inorganic layer in a nanostructure.

The growing of the organic or inorganic layer in the nanostructure may use a process including plating, chemical solution deposition, physical vapor deposition, or chemical vapor deposition.

Other features and aspects will be apparent from the following detailed description, the drawings, and the claims.

### BRIEF DESCRIPTION OF THE DRAWINGS

FIG. 1 is a flowchart illustrating an example of a method of manufacturing an electronic device.

FIG. 2 is a flowchart illustrating another example of a method of manufacturing an electronic device.

FIG. 3 is a flowchart illustrating still another example of a method of manufacturing an electronic device.

FIG. 4 is a flowchart illustrating yet another example of a method of manufacturing an electronic device.

FIG. 5 is scanning electron microscopy (SEM) images of zinc oxide (ZnO) nanorods grown based on a concentration of polyethyleneimine (PEI).

FIG. 6 is an x-ray diffraction (XRD) pattern graph of ZnO nanorods.

FIG. 7 is a Raman scattering spectrum of ZnO nanorods.

FIG. 8 is images of a polyethylene terephthalate (PET) substrate and a mica substrate on which ZnO nanorods are grown.

FIG. 9 is images of a PET substrate and a mica substrate on which ZnO nanorods are grown subsequent to a bending test.

FIG. 10 is a graph illustrating respective transparencies of PET, mica, indium tin oxide (ITO)/PET, ITO/mica, and thermally processed ITO/mica.

FIG. 11 is a graph illustrating respective resistances of ITO/PET, ITO/mica, and thermally processed ITO/mica.

FIG. 12 is a graph illustrating a relationship between a photocurrent density and a voltage of sample A and sample B.

FIG. 13 is a graph illustrating a relationship between a photocurrent density and a voltage of sample A and sample C.

FIG. 14 is a graph illustrating a relationship between a photocurrent density and a voltage of sample A and sample D.

FIG. 15 is a graph illustrating an output voltage of a nanogenerator.

FIG. 16 is a graph illustrating an output current density of a nanogenerator.

Throughout the drawings and the detailed description, unless otherwise described or provided, the same drawing reference numerals refer to the same elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the systems, apparatuses and/or methods described herein will be apparent to one of ordinary skill in the art. The progression of processing steps and/or operations is described as an example; the sequence of operations is not limited to that set forth herein and may be changed as is known in the art, with the exception of steps and/or operations that necessarily occur in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure is thorough, complete, and conveys the full scope of the disclosure to one of ordinary skill in the art.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “include” and/or “have,” when used in this specification, specify the presence of stated features, integers, steps, operations, elements, components or combinations thereof, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

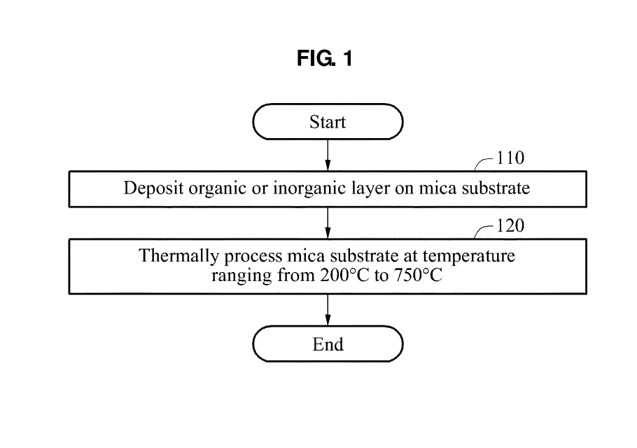

FIG. 1 is a flowchart illustrating an example of a method of manufacturing an electronic device.

Referring to FIG. 1, in operation 110, an organic or inorganic layer is deposited on a mica substrate.

A matter of the organic or inorganic layer to be deposited on the mica substrate may include at least one of graphene, graphene oxide, carbon nanotube, boron nitride (BN), silicon (Si), germanium (Ge), germanium sulfide (GeS), germanium disulfide (GeS₂), Ba₃F₂, magnesium fluoride (MgF₂), Lanthanum trifluoride (LaF₃), gallium fluoride (GaF₂), lithium fluoride (LiF), silicon carbide (SiC), aluminum nitride (AlN), aluminum phosphide (AlP), aluminum arsenide (AlAs), aluminum antimonide (AlSb), gallium nitride (GaN), gallium phosphide (GaP), gallium arsenide (GaAs), gallium tin (GaSb), indium nitride (InN), indium phosphide (InP), indium arsenide (InAs), indium tin (InSb), cadmium selenide (CdSe), cadmium sulfide (CdS), cadmium telluride (CdTe), zinc oxide (ZnO), zinx selenide (ZnSe), zinc sulfide (ZnS), zinc telluride (ZnTe), copper chloride (CuCl), copper (I) sulfide (Cu₂S), lead selenide (PbSe), lead(II) sulfide (PbS), leads telluride (PbTe), tin(II) sulfide (SnS), tin telluride (SnTe), lead tin telluride (PbSnTe), bismuth telluride (Bi₂Te₃), cadmium phosphide (Cd₃P₂), cadmium arsenide (Cd₃As₂), cadmium antimonide (Cd₃Sb₂), zinc phosphide (Zn₃P₂), zinc arsenide (Zn₃As₂), zinc antimonide (Zn₃Sb₂), aluminum oxide (Al₂O₃), titanium oxide (TiO₂), copper(I) oxide (Cu₂O), copper(II) oxide (CuO), Chromium(III) oxide (Cr₂O₃), cobalt oxide (Co₂O₃), boron trioxide (B₂O₃), bismuth oxide (Bi₂O₃), bismuth ferrite (BiFeO₃), bismuth titanate (Bi₄Ti₃O₁₂), tin oxide (SnO₂), barium titanate (BaTiO₃), strontium titanate (SrTiO₃), lithium metaniobate (LiNbO₃), lithium tantalite (LiTaO₃), lanthanum aluminate (LaAlO₃), La₂CuO₄, NdGaO₃, nickel(II) oxide (NiO), LiGaO₂, LiTaO₃, YAlOSiO₂, silicon nitride (SiN), magnesium oxide (MgO), manganese dioxide (MnO₂), V₂O₇, tungsten trioxide (WO₃), Na₂WO₃, sodium niobate (NaNbO₃), calcium oxide (CaO), molybdenum trioxide (MoO₃), cerium(IV) oxide (CeO₂), antimony trioxide (Sb₂O₃), strontium oxide (SrO), strontium calcium oxide (SrCaO), magnesium strontium oxide (MgSrO), magnesium calcium oxide (MgCaO), zirconium dioxide (ZrO₂), LaPO₄, tellurium dioxide (TeO₂), germanium dioxide (GeO₂) CoFeB, CoFe, iron nickel (NiFe), CoFePt, CoFePd, CoFeCr, CoFeTb, CoFeGd, CoFeNi, silver molybdate (Ag₂MoO₄), silver dimolybdate (Ag₂Mo₂O₇), Ag₂Mo₄O₁₃, silver tungstate (Ag₂WO₄), silver ditungstate (Ag₂W₂O₇), Ag₂W₄O₁₃, poly(methyl methacrylate) (PMMA), polydimethylsiloxane (PDMS), thiophene, polyvinylidene fluoride (PVDF), phenyl isocianate, styrene, tetramethyltin, indium tin oxide (ITO), indium(III) oxide (In₂O₃), tin dioxide (SnO₂), zinc oxide (ZnO), magnesium oxide (MgO), cadmium oxide (CdO), magnesium zinc oxide (MgZnO), indium zinc oxide (InZnO), indium tin oxide (InSnO), CuAlO₂, silver oxide (Ag₂O), gallium(III) oxide (Ga₂O₃), zinc tin oxide (ZnSnO), zinc doped indium tin oxide (ZITO), ZIO, GIO, ZTO, FTO, AZO, GZO, and In₄Sn₃O₁₂. However, the organic or inorganic layer may not be limited to the preceding types of matter.

Here, “depositing” may be construed as having a broad meaning including not only depositing an organic or inorganic layer but also growing all forms of matter or substances including semiconductors, conductors, and insulators. Thus, the depositing of the organic or inorganic layer on the mica substrate may be performed using at least one of plating, chemical solution deposition, physical vapor deposition, chemical vapor deposition, and atomic layer deposition. However, the depositing may not be limited to the preceding processes.

Mica or muscovite mica is an insulator, which is chemically inert, highly transparent, flexible, light, and stable even under being exposed to humidity, heat, and a high temperature. In addition to mica, metal foil, polyethylene terephthalate (PET), polyethylene naphthalate (PEN), or cellulose nanopaper may be used as a substrate for a flexible electronic device. However, aside from mica, the aforementioned insulators may be opaque or have a low maximum processing temperature. Further, mica has an extremely low thermal expansion coefficient of 9 to 35 parts per million per kelvin (ppm/K) compared to PET having a thermal expansion coefficient of 20 to 25 ppm/K and PEN having a thermal expansion coefficient of 18 to 20 ppm/K. Thus, mica may induce less tension between a substrate and a grown layer. Furthermore, mica may be readily processed as a substrate because mica has excellent cleavage properties. Mica splits into sheets having smooth, flat parallel surfaces, such that the two main axes of the sheets are nearly parallel to planes to be split, and mica may be split into extremely thin and flexible sheets of equal thicknesses.

Thin mica may be used to provide flexibility. A thickness of a mica substrate to be used for an electronic device may be less than or equal to 500 micrometers (μm). In detail, a thickness of the mica substrate may be in a range between greater than or equal to 10 μm and less than or equal to 500 μm. In a case that a thickness of the mica substrate exceeds 500 μm, a high flexibility and transparency may not be achieved.

In operation 120, the method thermally processes the mica substrate at a temperature of about 200° C. or greater. According to an embodiment the method thermally processes the mica substrate at a temperature ranging from 200° C. to 750° C.

Here, the mica substrate refers to the substrate on which the organic or inorganic layer is deposited. As described in the foregoing, “depositing” may be construed as having a broad meaning. In addition, “thermal processing” as used herein may be construed as having a broad meaning including performing a heat process or treatment or performing a thermal annealing process or treatment. Since mica is stable at a temperature less than or equal to 750° C., a high-temperature process may be performed after a semiconductor layer is deposited. Although PET, PEN, and nanopaper are flexible and transparent materials, PET, PEN, and nanopaper may not be easily used at a high temperature of greater than or equal to 78° C., 120° C., and 200° C., respectively. The mica substrate on which the organic or inorganic layer is deposited may be thermally processed, for example, at a temperature ranging from 200° C. to 750° C., or from 400° C. to 750° C., or more particularly, from 450° C. to 750° C.

However, the temperature may not be limited to the aforementioned ranges. In addition, a thermal processing time may change depending on a temperature. For example, the mica substrate may be thermally processed at 600° C. for 1 hour. In a case of the mica substrate being thermally processed at a higher temperature than 600° C., the mica substrate may be thermally processed for less than 1 hour. Conversely, in a case of the mica substrate being thermally processed at a lower temperature than 600° C., the mica substrate may be thermally processed for greater than or equal to 1 hour.

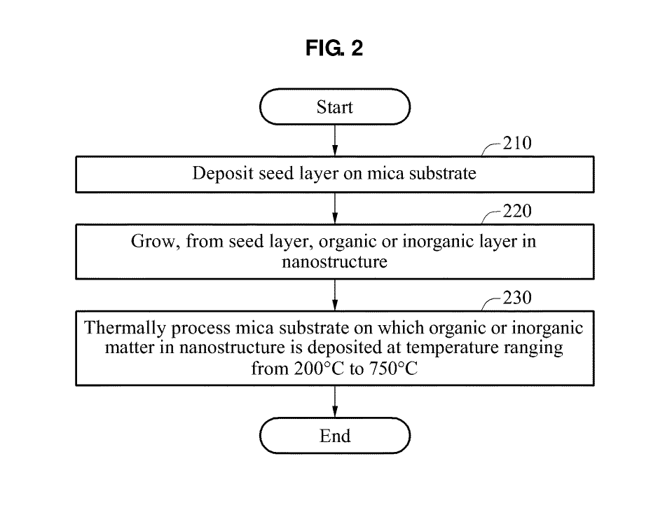

FIG. 2 is a flowchart illustrating another example of a method of manufacturing an electronic device.

Referring to FIG. 2, in operation 210, a seed layer is deposited on a mica substrate. The seed layer to be deposited on the mica substrate may be a metal-oxide seed layer. The depositing of the seed layer may be performed using at least one of plating, chemical solution deposition, physical vapor deposition, chemical vapor deposition, and atomic layer deposition. However, the depositing may not be limited to the preceding structures.

In operation 220, an organic or inorganic layer is grown from the seed layer in a nanostructure. The nanostructure is a structure of an intermediate size between a microscopic and a molecular structure, and may include, for example, nanoparticles, nanotubes, nanowires, nanofibers, nanoshells, nanorods, nanosheets or nanofilms such as a transparent conductive film. However, the nanostructure may not be limited to the preceding. The growing of organic or inorganic matter to be the nanostructure, more particularly, a form of nanorods, from the seed layer may be performed using at least one of plating, chemical solution deposition, physical vapor deposition, and chemical vapor deposition. However, the growing may not be limited to the preceding. In an example, in a case of using hydrothermal synthesis, the organic or inorganic matter to be grown to the form of nanorods may be a semiconductor, or more particularly, Ag, Ag₂Mo₂O₇, Ag₂WO₄, AlN, Al₂O₃, Au, B₂O₃, BaTiO₃, BiFeO₃, Bi₂O₃, Bi₂Te₃, Bi₄Ti₃O₁₂, CdS, CdSe, CdTe, CeO₂, CoFeB, Cr₂O₃, Cu, CuCl, CuO, Cu₂O, Cu₂S, FePt, GaAs, GaN, GaP, GaSb, Ge, GeO₂, InAs, InN, InP, InSb, La₂CuO₄, LaF₃, LaPO₄, LiCoO₂, LiMnO₂, LiF, LiNbO₃, MgF₂, MgO, MnO₂, MoO₃, NaNbO₃, NiO, PbS, PbSe, PbTe, Sb₂O₃, Si, SiC, SiN, SnO₂, SnS, SnTe, SrTiO₃, TiO₂, TeO₂, WO₃, ZnO, ZnS, ZnSe, ZnTe, or ZrO₂.

In operation 230, the mica substrate on which the organic or inorganic matter in the nanostructure is deposited, is thermally processed, for example, at a temperature of about 200° C. or greater. According to an embodiment, the mica substrate on which the organic or inorganic matter in the nanostructure is deposited may be thermally processed at a temperature ranging from 200° C. to 750° C. In an example, in a case that a dye-sensitized solar cell is manufactured using an electronic device thermally processed subsequent to a growth of the nanostructure, for example, the nanorods, an energy conversion efficiency may increase, as detailed in the following Example 5. In another example, in a case that a nanogenerator is manufactured using an electronic device thermally processed subsequent to a growth of the nanorods, an output voltage and an output current density may increase, as detailed in the following Example 6.

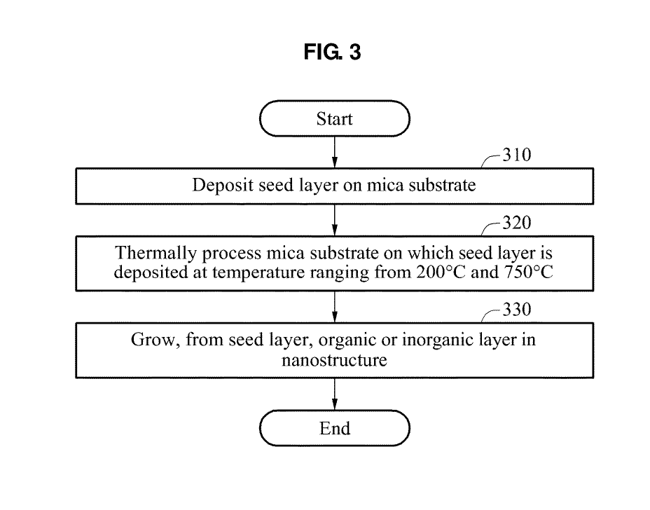

FIG. 3 is a flowchart illustrating still another example of a method of manufacturing an electronic device.

Referring to FIG. 3, in operation 310, a seed layer is deposited on a mica substrate. The seed layer to be deposited on the mica substrate may be a metal-oxide seed layer. The depositing of the seed layer may be performed using one of plating, chemical solution deposition, physical vapor deposition, chemical vapor deposition, and atomic layer deposition. However, the depositing may not be limited to the preceding processes.

In operation 320, the mica substrate on which the seed layer is deposited is thermally processed, for example, at a temperature ranging from 200° C. to 750° C. A high temperature may be applied to a process through which the seed layer is deposited. Alternatively, an additional thermal process may be performed subsequent to the seed layer being deposited. In an example, in a case of growing a nanostructure, for example, nanorods, on the mica substrate subsequent to the thermal processing of the mica substrate on which the seed layer is deposited, an adhesion between the nanorods and the mica substrate may be improved and the nanorods may grow in almost all regions without a non-growth region, as detailed in the following Example 3.

In operation 330, an organic or inorganic layer grows from the seed layer in the nanostructure. The growing or forming of organic or inorganic matter in the nanostructure from the seed layer may be performed, for example, using any one of plating, chemical solution deposition, physical vapor deposition, and chemical vapor deposition. However, the growing or the forming may not be limited to the preceding. In an example, in a case of using hydrothermal synthesis, the organic or inorganic matter to be grown to the nanostructure, for example, a form of nanorods, may be a semiconductor, or more particularly, Ag, Ag₂Mo₂O₇, Ag₂WO₄, AlN, Al₂O₃, Au, B₂O₃, BaTiO₃, BiFeO₃, Bi₂O₃, Bi₂Te₃, Bi₄Ti₃O₁₂, CdS, CdSe, CdTe, CeO₂, CoFeB, Cr₂O₃, Cu, CuCI, CuO, Cu₂O, Cu₂S, FePt, GaAs, GaN, GaP, GaSb, Ge, GeO₂, InAs, InN, InP, InSb, La₂CuO₄, LaF₃, LaPO₄, LiCoO₂, LiMnO₂, LiF, LiNbO₃, MgF₂, MgO, MnO₂, MoO₃, NaNbO₃, NiO, PbS, PbSe, PbTe, Sb₂O₃, Si, SiC, SiN, SnO₂, SnS, SnTe, SrTiO₃, TiO₂, TeO₂, WO₃, ZnO, ZnS, ZnSe, ZnTe, or ZrO₂.

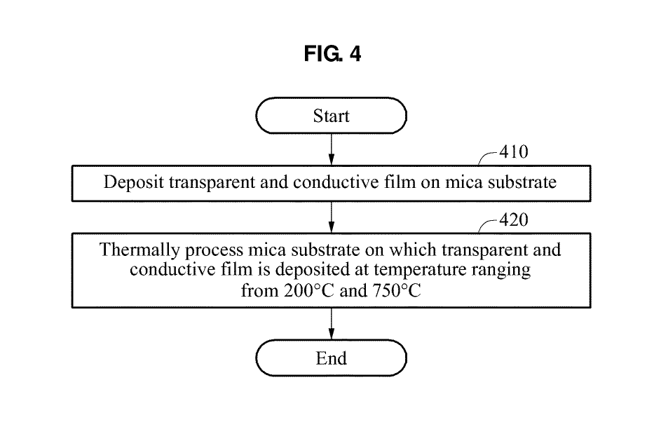

FIG. 4 is a flowchart illustrating yet another example of a method of manufacturing an electronic device.

Referring to FIG. 4, in operation 410, a transparent conductive film is deposited on a mica substrate.

The depositing of the transparent conductive film on the mica substrate may be performed, for example, using any one of plating, chemical solution deposition, physical vapor deposition, and chemical vapor deposition. However, the depositing may not be limited to the preceding. The transparent conductive film may include a transparent conductive oxide, and at least one of ITO, In₂O₃, SnO₂, ZnO, MgO, CdO, MgZnO, InZnO, InSnO, CuAlO₂, Ag₂O, Ga₂O₃, ZnSnO, ZITO, ZIO, GIO, ZTO, FTO, AZO, GZO, and In₄Sn₃O₁₂. However, the transparent conductive film may not be limited to the preceding. In detail, ITO may be included, in a form of a film, in an organic or inorganic layer.

In operation 420, the mica substrate on which the transparent conductive film is deposited is thermally processed, for example, at a temperature of about 200° C. or greater. According to an embodiment, the mica substrate on which the transparent conductive film is deposited may be thermally processed at a temperature ranging from 200° C. to 750° C. In an example, subsequent to the thermal processing, the mica substrate on which the transparent conductive film is deposited may have an improved transparency and a reduced sheet resistance, as detailed in the following Example 4.

According to an embodiment, an electronic device includes a mica substrate, and an organic or inorganic layer formed on the mica substrate. The organic or inorganic layer may include a nanostructure or a transparent conductive film, and the electronic device may be thermally processed at a temperature of about 200° C. or greater. According to a further embodiment, the electronic device may be thermally processed at a temperature ranging from 200° C. to 750° C. The mica substrate may be transparent and flexible, and may have a thickness less than or equal to 500 μm.

According to an embodiment, a dye-sensitized solar cell may include a transparent electrode, a counter electrode, a dye, and an electrolyte. The transparent electrode may include an electronic device manufactured through the method described in the foregoing.

According to an embodiment, a piezoelectric nanogenerator may include an electronic device manufactured through the method described in the foregoing.

Additional representative embodiments will now be described in the following experimental Examples 1-6.

### Example 1

### Growing Zinc Oxide (ZnO) Nanorods on a Mica Substrate

Characteristics of ZnO nanorods grown on a mica substrate were examined.

Muscovite mica from Ted Pella Inc. was used as the mica substrate, and the mica substrate was prepared by splitting the muscovite mica to have a thickness of 500 μm. The prepared mica substrate was ultrasonically cleaned in acetone for 10 minutes and rinsed with deionized (DI) water. A ZnO seed layer was deposited on the mica substrate using a sol-gel spin-coating process. A sol-gel solution was prepared by diluting 0.005 mol/l (M) of zinc acetate dehydrate (Zn(CH₃COO)₂.2H₂O, 99%, from Sigma-Aldrich) with ethanol. The mica substrate on which the ZnO seed layer was deposited was thermally processed at 350° C. for 20 minutes to evaporate a solvent and remove organic residues. The spin-coating and the thermal processing were repeated four times. The ZnO was thermally processed at 500° C. for 30 minutes for crystallization.

Hydrothermal synthesis was used to grow the ZnO nanorods from the ZnO seed layer. An aqueous solution of 0.05 M of zinc nitrate hexahydrate (Zn(NO₃)₂.6H₂O, 99%, from Sigma-Aldrich), 0.05 M of hexamethylenetetramine (C₆H₁₂N₄, 99.5%, from Sigma-Aldrich), 0.005 to 0.015 M of PEI (end-capped, molecular weight 800 g/mol LS, from Sigma-Aldrich), and 0.1 to 0.4 M of ammonium hydroxide (NH₄OH, 28-30%, from Sigma-Aldrich) was prepared. A growth temperature was varied in a range between 75° C. and 95° C. to examine an influence of a temperature on the growth of the ZnO nanorods. After reaction to the hydrothermal synthesis for 9 hours, a ZnO nanorod sample grown on the mica substrate was rinsed with DI water and dried under natural conditions.

1) Concentration of Polyethyleneimine (PEI)

To examine a growth of ZnO nanorods based on a concentration of PEI, an aqueous solution for hydrothermal synthesis included 0.05 M of Zn(NO₃)₂.6H₂O and 0.05 M of C₆H₁₂N₄ at a temperature of 90° C., and the temperature was maintained. Here, 0 M, 0.005 M, 0.0075 M, and 0.01 M or 0.015 M of PEI was used.

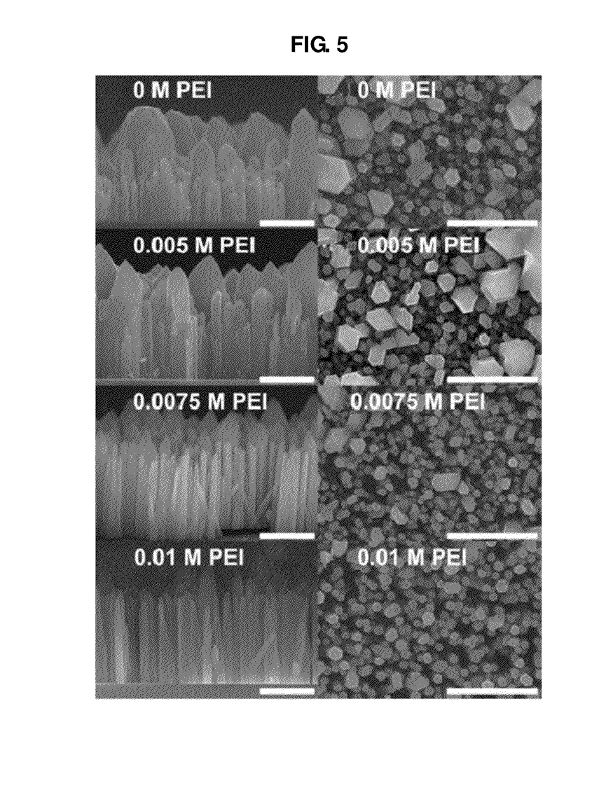

FIG. 5 is scanning electron microscope (SEM) images of ZnO nanorods grown based on a concentration of PEI. A scale bar of each SEM image indicates 1 μm. At a low concentration of PEI, for example, at 0 M and 0.005 M, nanorods with large diameters were sparsely formed and lengths of the nanorods were not equal. With an increase in a concentration of PEI, the diameters and the lengths of the nanorods were equalized. At a concentration of PEI greater than or equal to 0.015 M, the nanorods were not grown on the mica substrate.

In the growth of the nanorods based on a concentration of PEI, PEI at an excessive concentration may hinder nucleation on a ZnO seed layer. Thus, under the conditions of the 0.05 M of Zn(NO₃)₂.6H₂O and 0.05 M of C₆H₁₂N₄ and the temperature of 90° C., an optimal concentration of PEI may be 0.01 M. However, the growth of nanorods may be affected by another condition.

2) Temperature

To examine a growth of ZnO nanorods based on a temperature, an aqueous solution for hydrothermal synthesis included 0.05 M of Zn(NO₃)₂.6H₂O, 0.05 M of C₆H₁₂N₄, and 0.01 M of PEI. Here, a temperature of 75° C., 85° C., or 95° C. was applied to grow the nanorods.

At 75° C., diameters of the grown nanorods were equal, but lengths of the nanorods were not equal. At 95° C., the diameters of the grown nanorods were not equal, but the lengths of the nanorods were equal. At 85° C., both the diameters and the lengths of the grown nanorods were relatively equal.

Thus, an average length and diameter of grown nanorods may be affected by temperature. The unequal diameters of the nanorods at a high temperature may be due to an excessively fast decomposition rate of C₆H₁₂N₄ and a production of OH⁻ that is excessive for growth of ZnO. Thus, nanorods having equal diameters and lengths may be grown at 85° C. However, the growth of nanorods may be affected by another condition.

3) Concentration of NH₄OH

In hydrothermal synthesis, ZnO may be formed as a white deposit due to a high degree of supersaturation of ZnO. Thus, ammonium hydroxide (NH₄OH) is added to reduce the ZnO deposit and maintain a growth speed of ZnO nanorods. Ammonia functions based on the following reaction formula: Zn₂₊+nNH₃ [symbol] Zn(NH₃)n²⁺, wherein “n” is 1, 2, 3, or 4.

To examine a growth of the ZnO nanorods depending on a concentration of NH₄OH, an aqueous solution for the hydrothermal synthesis included 0.05 M of Zn(NO₃)₂.6H₂O, 0.05 M of C₆H₁₂N₄, and 0.01 M of PEI at a temperature of 85° C. The nanorods were grown at various concentrations of NH₄OH, for example, at 0.1 M, 0.15 M, and 0.2 M or 0.25 M.

An average length and an average diameter of the nanorods increased as a concentration of NH₄OH increased. At a concentration greater than or equal to 0.25 M of NH₄OH, the grown ZnO nanorods did not completely cover a surface of the mica substrate. Such a failure in the complete covering of the substrate resulted from the nucleation needed for the growth of the ZnO nanorods being inhibited when a concentration of NH₄OH increases to a certain level or higher.

Thus, the ZnO nanorods grown in the aqueous solution including 0.01 M of PEI and 0.4 M of NH₄OH at 85° C. were successfully grown to be vertically well-aligned. The average length and the average diameter of such grown nanorods were 4.88 μm and 170 nanometers (nm), respectively.

### Example 2

### Determining ZnO Crystals Thermally Processed Subsequent to Growth

1) X-Ray Diffraction (XRD) Pattern

To examine an effect of a thermal process in structural characteristics of ZnO nanorods grown on a mica substrate, the thermal process was performed at 500° C. for 30 minutes subsequent to the growth.

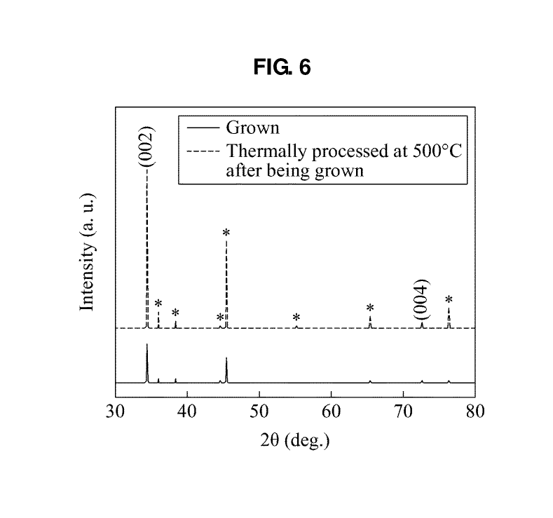

FIG. 6 is an XRD pattern graph of ZnO nanorods, which includes an XRD pattern of ZnO nanorods grown without a thermal process and an XRD pattern of ZnO nanorods thermally processed subsequent to a growth.

Referring to FIG. 6, in the two cases, two diffraction peaks were observed at 34.48° and 72.54°, respectively, which correspond to ZnO crystal phases, for example 002 and 004. All peaks in the obtained spectrum, excluding peaks marked as asterisks from the mica substrate, were indexed to hexagonal or hexagonal-system ZnO, which indicates that all ZnO nanorods are in a single-phase structure. A diffraction peak intensity 002 of ZnO nanorods was higher than another diffraction peak intensity of the ZnO nanorods, which indicates that a preferred growth direction is an axis of a crystal (c-axis).

2) Raman Scattering

An optical characteristic of ZnO nanorods was examined using a Raman scattering method. ZnO has a wurtzite crystal structure. Raman active phonon modes in ZnO are E₂ (low)=102 cm-1, E₂ (high)=437 cm-1, E₁ (TO)=410 cm-1, E₁ (LO)=591 cm-1, A₁ (TO)=379 cm-1, and A₁ (LO)=577 cm-1.

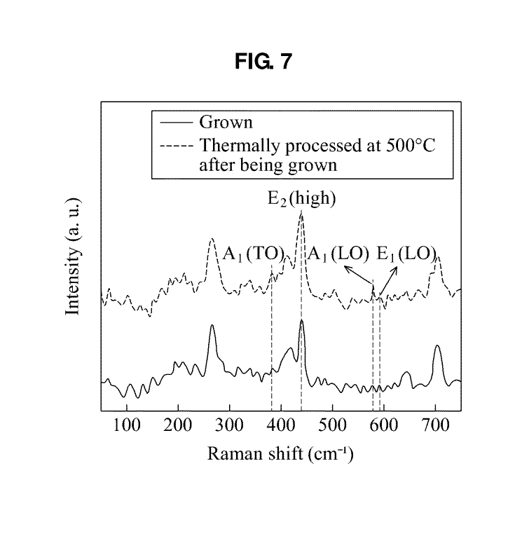

FIG. 7 is a Raman scattering spectrum of ZnO nanorods, which includes a Raman scattering spectrum of ZnO nanorods grown without a thermal process, and a Raman scattering spectrum of ZnO nanorods thermally processed subsequent to a growth. Referring to FIG. 7, a sharp and strong peak at 438.5 cm-1 corresponds to an E₂ (high frequency) phonon mode. Since E₁ (LO) relates to a structural flaw and impurities, an extremely low intensity of E₁ (LO) at 591 cm-1 indicates that the ZnO nanorods thermally processed subsequent to the growth have a favorable crystalline quality.

Thus, thermally processed ZnO nanorods may have a vertically well-aligned crystal structure and a good crystalline quality with fewer structural flaws or impurities.

### Example 3

### A Coverage and Adhesion of ZnO Nanorods on a Mica Substrate, when the ZnO Nanorods are Thermally Processed Prior to Growing the ZnO Nanorods

A thermal process was performed at a high temperature, for example, evaporation was performed at 350° C. for 20 minutes and crystallization was performed at 500° C. for 30 minutes, to evaporate a solvent used in a spin-coating process and crystallize a ZnO seed layer, prior to growing ZnO nanorods from the ZnO seed layer on a mica substrate. The ZnO nanorods were grown, through hydrothermal synthesis, from the ZnO seed layer on the thermally processed mica substrate. A PET substrate having a thickness equal to a thickness of the mica substrate was prepared and ZnO nanorods were grown on the PET substrate through hydrothermal synthesis.

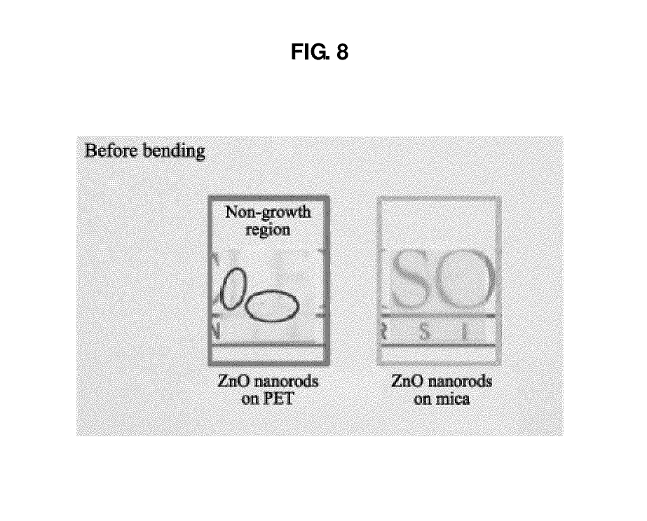

FIG. 8 is images of a PET substrate and a mica substrate on which ZnO nanorods are grown. In a case of the PET substrate, a non-growth region of the ZnO nanorods was observed in a portion of the PET substrate. In a case of the mica substrate, a favorable coverage was observed without a non-growth region in almost all portions of the mica substrate.

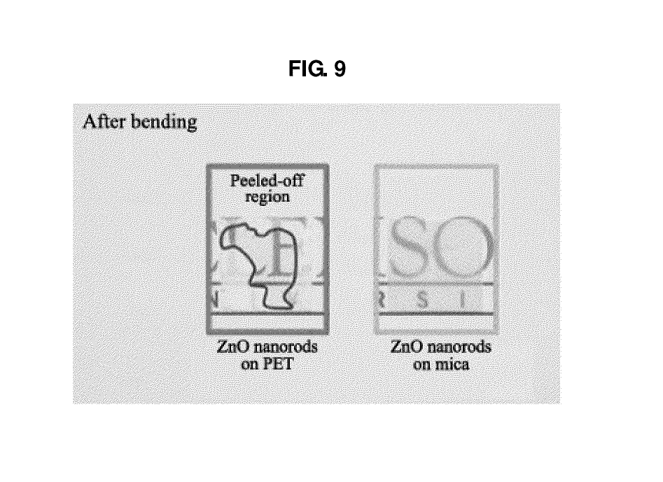

FIG. 9 is images of a PET substrate and a mica substrate on which ZnO nanorods are grown subsequent to a bending test. A bending test with a bending radius of 5 millimeters (mm) was performed 1000 times. Subsequent to the bending test, a considerable number of the ZnO nanorods on the PET substrate were peeled off from the PET substrate, but no ZnO nanorods on the mica substrate were peeled off. Despite the bending test being performed 1000 times, the mica substrate remained flexible without breaks or cracks.

Thus, in a case of performing a thermal process prior to growing ZnO nanorods, the ZnO nanorods grown on the mica substrate may desirably cover an overall portion of the mica substrate and an adhesion between the ZnO nanorods and the mica substrate may be improved.

### Example 4

### A Transparency and Resistance of Thermally Processed ITO/Mica

1) Transparency

To examine an influence of a thermal process on a transparency of a substrate, a PET, a mica, an ITO/PET, an ITO/mica, and a thermally processed ITO/mica substrate having identical sizes and thicknesses were prepared. An ITO/mica substrate thermally processed at 500° C. for 30 minutes was used for the test. A transparency spectrum in a range between 200 nm and 1100 nm wavelengths was examined for each case.

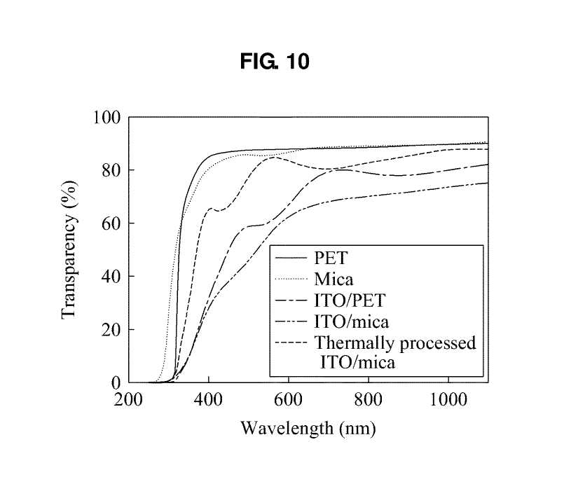

FIG. 10 is a graph illustrating respective transparencies of the PET, the mica, the ITO/PET, the ITO/mica, and the thermally processed ITO/mica. Referring to FIG. 10, transparencies of the PET and the mica were similar in the range between 200 nm and 1100 nm wavelengths. Transparencies of the ITO/PET and the ITO/mica with an ITO film deposited on the PET and the mica, respectively, were considerably reduced from the original transparencies of the PET and the mica. However, a transparency of the ITO/mica thermally processed at 500° C. for 30 minutes increased.

2) Resistance

To examine an influence of a thermal process on a resistance of a substrate, an ITO/PET, an ITO/mica, and a thermally processed ITO/mica were prepared. Here, an ITO/mica thermally processed at 500° C. for 30 minutes was used for the test.

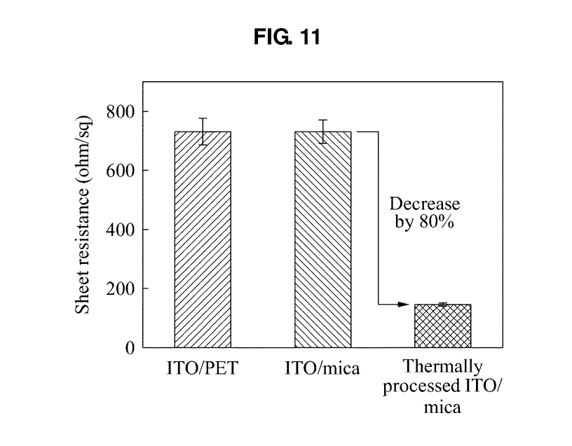

FIG. 11 is a graph illustrating respective resistances of the ITO/PET, the ITO/mica, and the thermally processed ITO/mica. Referring to FIG. 11, a resistance of the thermally processed ITO/mica decreased by approximately 80% compared to the ITO/mica which is not thermally processed.

TABLE 1

| | Transparency (%) | Sheet resistance |
|---|---|---|
| | at 550 nm | (ohm/sq) |
| PET | 87.9 | N/A |
| Mica | 86.0 | N/A |
| ITO/PET | 60.3 | 731.6 ± 44.5 |
| ITO/mica | 55.3 | 732.4 ± 37.0 |
| Thermally processed ITO/mica | 84.3 | 147.1 ± 4.4 |

Table 1 indicates respective transparencies and resistances of the PET, the mica, the ITO/PET, the ITO/mica, and the thermally processed ITO/mica at a 550 nm wavelength. Referring to Table 1, the thermally processed ITO/mica has an improved transparency and conductivity compared to the ITO/mica which is not thermally processed.

Thus, using mica as a substrate in lieu of PET, which is not easy to be thermally processed at a high temperature greater than or equal to 78° C., may enable a high-temperature process. Through such a high-temperature process, a transparency and a conductivity may be improved.

### Example 5

### Dye-Sensitized Cells

To examine an influence of a growth time of ZnO nanorods and a thermal process on dye-sensitized solar cells (DSSCs), four DSSC samples were prepared, all of which include ZnO nanorods grown on a mica substrate. Sample A included ZnO nanorods grown for 9 hours, and sample B included ZnO nanorods grown for 18 hours. Sample C included ZnO nanorods thermally processed after being grown for 9 hours, and sample D included ZnO nanorods thermally processed after being grown for 18 hours.

TABLE 2

| | Growth time | | Time of | | | |
|---|---|---|---|---|---|---|
| | of ZnO | Temperature | thermal | | | Effi- |
| | nanorods | of thermal | process | V_{OC} | J_{SC} | ciency |
| | (h) | process (° C.) | (h) | (V) | (mA/cm²) | (%) |
| A | 9 | As-grown | — | 0.48 | 2.39 | 0.36 |
| B | 18 | As-grown | — | 0.52 | 3.28 | 0.51 |
| C | 9 | 500 | 0.5 | 0.57 | 3.24 | 0.55 |
| D | 18 | 500 | 0.5 | 0.65 | 3.95 | 0.69 |

Table 2 indicates a voltage, a current intensity, and an efficiency of DSSCs including sample A, sample B, sample C, or sample D.

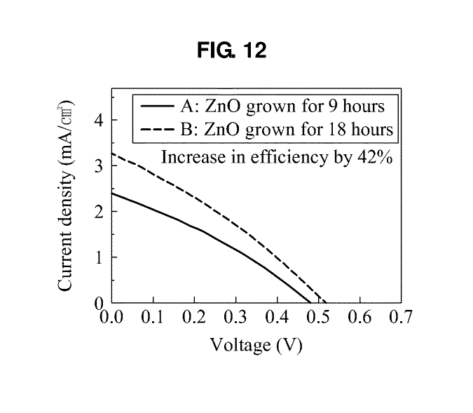

FIG. 12 is a graph illustrating a relationship between a photocurrent density and a voltage of sample A and sample B. Referring to FIG. 12, an efficiency of sample B with 18 hours of the growth time is 42% higher compared to sample A with 9 hours of the growth time.

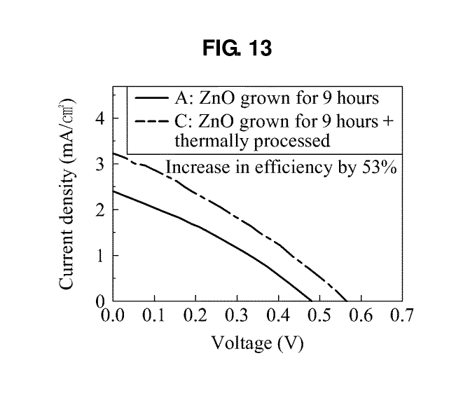

FIG. 13 is a graph illustrating a relationship between a photocurrent density and a voltage of sample A and sample C. Referring to FIG. 13, despite an equal amount of the growth time of 9 hours, an efficiency of sample C including the nanorods thermally processed subsequent to the growth is 53% higher compared to sample A.

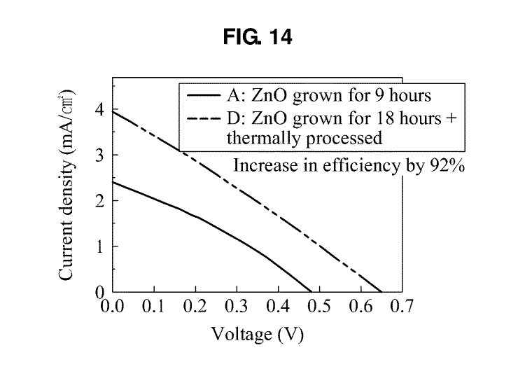

FIG. 14 is a graph illustrating a relationship between a photocurrent density and a voltage of sample A and sample D. Referring to FIG. 14, an efficiency of sample D thermally processed subsequent to the growth and having a longer growth time is 92% higher compared to sample A.

An efficiency of DSSCs including nanorods thermally processed subsequent to a growth may considerably increase, and the increased efficiency may be similar to an efficiency of DSSCs including nanorods grown more than two times. Thus, thermally processing the grown nanorods may enable an increase in an efficiency of DSSCs and a reduction in a growth time of the nanorods.

### Example 6

### A Nanogenerator

To examine an influence of ZnO nanorods thermally processed after being grown on a nanogenerator or a piezoelectric nanogenerator, a nanogenerator including ZnO nanorods thermally processed after being grown and a nanogenerator including ZnO nanorods without being thermally processed after being grown were fabricated.

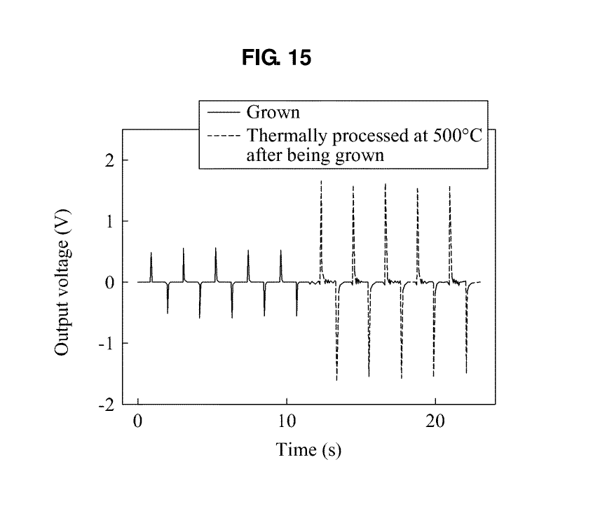

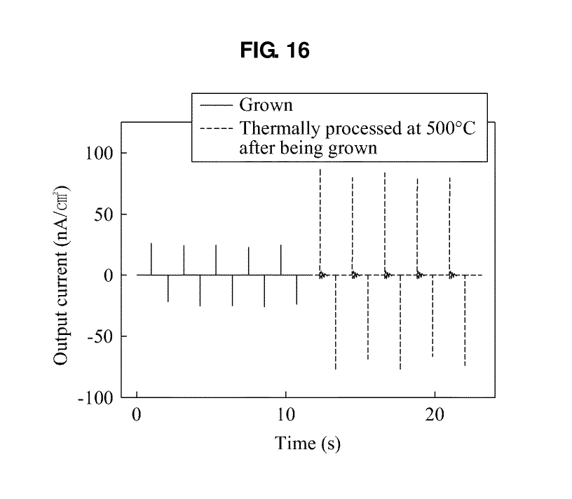

FIG. 15 is a graph illustrating an output voltage of a nanogenerator, and FIG. 16 is a graph illustrating an output current density of a nanogenerator. Referring to FIGS. 15 and 16, an output voltage of the nanogenerator including the ZnO nanorods without being thermally processed is approximately 0.5 volts (V), and an output voltage of the nanogenerator including the thermally processed ZnO nanorods is approximately 1.5 V. In addition, an output current density of the nanogenerator including the ZnO nanorods without being thermally processed is approximately 25 nanoamperes/centimeter2 (nA/cm2), and an output current density of the nanogenerator including the thermally processed ZnO nanorods is approximately 80 nA/cm2. The output voltage and the output current density of the nanogenerator including the thermally processed ZnO nanorods are approximately three-fold greater than those of the nanogenerator including the ZnO nanorods without being thermally processed.

Thus, such a post-growth thermal process performed on the ZnO nanorods may improve a crystalline quality by reducing an oxygen-vacancy-related defect and accordingly, increase a piezoelectric potential in the ZnO nanorods.

An electronic device as disclosed herein may be, for example, a flexible and transparent device, and may include components such as a thin-film transistor, a light-emitting diode (LED), a solar cell, or a supercapacitor. However, the electronic device may be another type of device, and may include components other than the listed components.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A method of manufacturing an electronic device, the method comprising:
forming an organic or inorganic layer on a mica substrate; and
thermally processing the mica substrate at a temperature of 200° C. or greater.

2. The method of claim 1, wherein the mica substrate has a thickness less than or equal to 500 micrometers (μm).

3. The method of claim 1, wherein the forming of the organic or inorganic layer comprises:
depositing a seed layer on the mica substrate; and
growing, from the seed layer, the organic or inorganic layer in a nanostructure.

4. The method of claim 3, wherein the thermal processing is performed subsequent to the depositing of the seed layer on the mica substrate.

5. The method of claim 3, wherein the thermal processing is performed subsequent to the growing of the organic or inorganic layer in the nanostructure.

6. The method of claim 3, wherein the growing of the organic or inorganic layer in the nanostructure uses a process selected from the group consisting of plating, chemical solution deposition, physical vapor deposition, and chemical vapor deposition.

7. The method of claim 1, wherein:
the forming of the organic or inorganic layer on the mica substrate uses a process selected from the group consisting of plating, chemical solution deposition, physical vapor deposition, and chemical vapor deposition; and
the organic or inorganic layer comprises a transparent conductive film.

8. The method of claim 1, wherein the thermally processing the mica substrate at the temperature of 200° C. or greater comprises thermally processing the mica substrate at a temperature ranging from 200° C. to 750° C.

9. The method of claim 1, wherein the thermally processing results in increasing at least one of a transparency and a conductivity of the electronic device in a form including an organic or inorganic layer disposed on a mica substrate.

10. The method of claim 9, wherein the thermally processing the electronic device is performed at a temperature ranging from 200° C. to 750° C.

11. The method of claim 9, wherein the organic or inorganic layer comprises indium tin oxide.

12. An electronic device, comprising:
a mica substrate; and
an organic or inorganic layer formed on the mica substrate,
wherein the organic or inorganic layer comprises a nanostructure or a transparent conductive film, and
wherein the electronic device is thermally processible at a temperature of 200° C. or greater.

13. The electronic device of claim 12, wherein the mica substrate has a thickness less than or equal to 500 micrometers (μm), and is transparent and flexible.

14. The electronic device of claim 12, wherein the electronic device is processible at a temperature ranging from 200° C. to 750° C.

15. An electronic device, comprising:
a mica substrate; and
an organic or inorganic layer disposed on the mica substrate,
wherein the electronic device is manufactured by
forming the organic or inorganic layer on the mica substrate, and
thermally processing the mica substrate at a temperature of 200° C. or greater.

16. The electronic device of claim 15, wherein the forming of the inorganic or organic layer on the mica substrate comprises:
depositing a seed layer on the mica substrate; and
growing, from the seed layer, the organic or inorganic layer in a nanostructure.

17. The electronic device of claim 16, wherein the growing of the organic or inorganic layer in the nanostructure uses a process selected from the group consisting of plating, chemical solution deposition, physical vapor deposition, and chemical vapor deposition.

18. The electronic device of claim 12, wherein the thermally processing results in increasing at least one of a transparency and a conductivity of the electronic device.

19. The electronic device of claim 18, wherein the thermally processing the electronic device is performed at a temperature ranging from 200° C. to 750° C.

20. The electronic device of claim 18, wherein the organic or inorganic layer comprises indium tin oxide.
